(19) United States
(12) Patent Application Publication
(10) Pub. No.: US 2017/0222004 A1
(43) Pub. Date: Aug. 3, 2017

(54) SEMICONDUCTOR DEVICE AND TRANSMITTER

(71) Applicant: FUJITSU LIMITED, Kawasaki-shi (JP)

(72) Inventor: MASARU SATO, Isehara (JP)

(73) Assignee: FUJITSU LIMITED, Kawasaki-shi (JP)

(21) Appl. No.: 15/386,025

(22) Filed: Dec. 21, 2016

(30) Foreign Application Priority Data
Feb. 1, 2016 (JP) 2016-017182

(51) Int. Cl. H01L 29/423; H01L 29/778; H01L 29/417; H01L 23/66; H03F 3/24; H01L 23/482; H01L 27/06; H03F 1/02; H03F 3/193; H01L 29/20; H01L 23/64

(52) U.S. Cl. CPC H01L 29/42316; H01L 29/2003; H01L 29/7787; H01L 29/41758; H01L 23/66; H01L 23/645; H01L 23/4821; H01L 27/0605; H03F 1/0205; H03F 3/193; H03F 3/245; H03F 2200/451; H03F 2200/108

(57) ABSTRACT

An amplifier has a plurality of gate finger electrodes, two gate connection electrodes, a plurality of source electrodes and a plurality of drain electrodes, and a plurality of drain connection elements. The plurality of gate finger electrodes are arranged pectinate on the surface of the active region of the semiconductor substrate. The two gate connection electrodes connect in common each of both ends of the plurality of gate finger electrodes. The plurality of source electrodes and the plurality of drain electrodes are arranged alternately on the surface of the semiconductor substrate between the plurality of gate finger electrodes. The plurality of drain connection elements connects in sequence the plurality of drain electrodes. The ratio of the inductance value of each drain connection element to the parasitic capacitance of the drain-source electrodes between the corresponding drain electrode and the source electrode is constant.

### CROSS-REFERENCE TO RELATED APPLICATION

This application is based upon and claims the benefit of priority of the prior Japanese Patent Application No. 2016-017182, filed on Feb. 1, 2016, the entire contents of which are incorporated herein by reference.

### FIELD

The present invention relates to a semiconductor device and a transmitter.

### BACKGROUND

A power amplifier amplifies a signal and in particular, a high-frequency power amplifier is used in a wireless communication device and in a transmission unit of a radar device. It is desirable to increase transmission power in order to extend the reachable distance of radio waves. The output power of a power amplifier (transistor) is determined based on the physical properties of the transistor, and in recent years, the output power is increased by using a gallium nitride (GaN) HEMT or the like.

It is known that the output power of one transistor is proportional to the gate width of the transistor. The output power of a transistor may be increased by increasing the gate width of the transistor, without changing the structure and physical properties of the transistor. However, when the gate width of the transistor is increased, the gate resistance increases and the gain may be remarkably reduced in the high-frequency region. Thus, it is not easy to increase the gate width and there is a limit to an increase in output power by increasing the gate width of the transistor.

Thus, higher output power is obtained by forming a plurality of transistors on a semiconductor substrate, inputting the same signal to the plurality of transistors, and combining the outputs. In other words, the total gate width is increased by combining the gate widths of a plurality of transistors. The output power of an amplifier is a value obtained by subtracting the loss at the time of combination from the upper limit of the product of the output power per transistor and the number of transistors.

When a plurality of transistors are arranged in order to increase the total gate width, a plurality of gate electrodes are arranged pectinate in the direction (Y-direction) perpendicular to the lengthwise direction (X-direction) of the gate electrode. A number of gate electrodes arranged pectinate are referred to as a gate finger. Further, a plurality of gate fingers are also arranged in the lengthwise direction (X-direction) of the gate electrode. In other words, a plurality of transistors are arranged two-dimensionally. In order to implement such arrangement, a transistor region becomes large and the chip size in the Y-direction is determined by the product of the pitch of the gate finger and the number of gate fingers. The chip size in the X-direction is determined by the product of the sum of the gate width, the width of the wire and the width of the separation region, and the number of rows of the gate finger.

Further, the density of transistors may be increased in order to increase the total gate width of the transistor while keeping the chip region constant. However, if the density of transistors is increased, heat generated by the transistor remains inside and the temperature of the chip rises. The amplification gain may be reduced by increasing the temperature.

### RELATED DOCUMENTS

[Patent Document 1] Japanese Laid Open Patent Document No. H10-242169

[Patent Document 2] Japanese Laid Open Patent Document No. 2012-234910

[Patent Document 3] Japanese Laid Open Patent Document No. 2005-183770

[Non-Patent Document 1] “Thermal Analysis of GaN Devices” Charles Suckling and Deena Nguyen, Arms RF and Microwave Society, 2012 Conference

### SUMMARY

The semiconductor device of a first aspect has a semiconductor substrate and an amplifier formed on the semiconductor substrate. The amplifier has a plurality of gate finger electrodes, two gate connection electrodes, a plurality of source electrodes and a plurality of drain electrodes, and a plurality of drain connection elements. The plurality of gate finger electrodes are arranged pectinate on the surface of the active region of the semiconductor substrate. The two gate connection electrodes connect in common each of both ends of the plurality of gate finger electrodes. The plurality of source electrodes and the plurality of drain electrodes are arranged alternately on the surface of the semiconductor substrate between the plurality of gate finger electrodes. The plurality of drain connection elements connects in sequence the plurality of drain electrodes. The ratio of the inductance value of each drain connection element to the parasitic capacitance of the drain-source electrodes between the corresponding drain electrode and the source electrode is constant.

The object and advantages of the embodiments will be realized and attained by means of the elements and combination particularly pointed out in the claims.

It is to be understood that both the foregoing general description and the following detailed description are exemplary and explanatory and are not respective of the invention.

### BRIEF DESCRIPTION OF DRAWINGS

FIG. 1A is a diagram illustrating a layout of an arrangement example of a plurality of transistors;

FIG. 1B is an equivalent circuit of the arrangement example illustrated in FIG. 1A;

FIG. 2 illustrates a change in thermal resistance of a chip for the gate finger interval (pitch) of a transistor normalized by the substrate thickness;

FIG. 3A illustrates a circuit diagram of a high-frequency power amplifier of a first embodiment;

FIG. 3B illustrates part of a layout illustrates part of a layout;

FIG. 4A illustrates the layout of a comparative example described in FIG. 1;

FIG. 4B illustrates the frequency characteristics of the maximum available gain of the high-frequency power amplifier of the first embodiment;

FIG. 5A illustrates the layout of the high-frequency power amplifier of the comparative example;

FIG. 5B is illustrates the frequency characteristics of the maximum available gain of the high-frequency power amplifier of the first embodiment;

FIG. 6 is a diagram illustrating power efficiency of the high-frequency power amplifier of the first embodiment and that of the comparative example with the layout in FIG. 5A, and the solid line indicates the characteristics of the high-frequency power amplifier of the first embodiment and the dot line indicates the characteristics of the comparative example;

FIG. 7 is a diagram in which a graph representing the size of a transistor that is arranged is added to the graph representing the change in thermal resistance of the chip for the transistor interval (pitch)/substrate thickness (L_{gg}/h) in FIG. 2 is added;

FIG. 8 is a diagram in which a graph representing the characteristic impedance calculated from the inductance value L of the inductor and C_{ds} for the transistor interval is added in place of the graph representing the transistor size in FIG. 7;

FIG. 9 is a diagram illustrating a layout configuration of a high-frequency power amplifier of a second embodiment, illustrating a top view and sectional views in two directions;

FIG. 10 is a diagram illustrating an equivalent circuit of the transistor row by one gate finger row of the high-frequency power amplifier of the second embodiment;

FIG. 11A illustrates an outline layout of a layout example of a transistor row corresponding to one gate finger row in a high-frequency power amplifier of a third embodiment;

FIG. 11B illustrates a specific layout configuration of the layout example illustrated in FIG. 11A;

FIG. 12 is a diagram illustrating an equivalent circuit of the transistor row by one gate finger row of the high-frequency power amplifier of the third embodiment;

FIG. 13A illustrates a layout of a configuration of the transistor row corresponding to the one gate finger row in a high-frequency power amplifier of a first comparative example;

FIG. 13B illustrates an equivalent circuit of the configuration illustrated in FIG. 13A;

FIG. 14A illustrates a layout of a configuration of the transistor row corresponding to the one gate finger row in a high-frequency power amplifier of a second comparative example;

FIG. 14B illustrates an equivalent circuit of the configuration illustrated in FIG. 14A;

FIG. 15A illustrates the frequency characteristics of the maximum available gain in the high-frequency power amplifiers of the second embodiment;

FIG. 15B illustrates the frequency characteristics of the maximum available gain in the high-frequency power amplifiers of the third embodiment;

FIG. 15C illustrates the frequency characteristics of the maximum available gain in the high-frequency power amplifiers of the first comparative example; and

FIG. 15D illustrates the frequency characteristics of the maximum available gain in the high-frequency power amplifiers of the second comparative example.

### DESCRIPTION OF EMBODIMENTS

Before explaining embodiments, a semiconductor device having a high-frequency and high-output amplifier is explained.

The radio communication device and the transmission unit of a radar device that output a high-frequency signal are desired to have a semiconductor device including a high-output amplifier (power amplifier) and to increase transmission power. It is common for the above-described power amplifier to be implemented by a transistor. The output power of a transistor is determined based on the physical properties of the transistor and in recent years, the output is increased by using a gallium nitride (GaN) HEMT or the like. When the structure and physical properties of the transistor is not changed, the output power of a transistor may be increased by increasing the gate width of the transistor.

Although the output power of a transistor is proportional to the gate width, when the gate width of the transistor is increased, the gate resistance increases and the gain may be remarkably reduced in the high-frequency region. Thus, the gate width is not increased so much and there is a limit to a method of increasing the gate width itself.

Thus, higher output power is obtained by forming a plurality of transistors on a semiconductor substrate, inputting the same signal to the plurality of transistors, and combining the outputs. In other words, the total gate width is increased by combining the gate widths of a plurality of transistors. The output power of an amplifier is a value obtained by subtracting the loss at the time of combination from the upper limit of the product of the output power per transistor and the number of transistors.

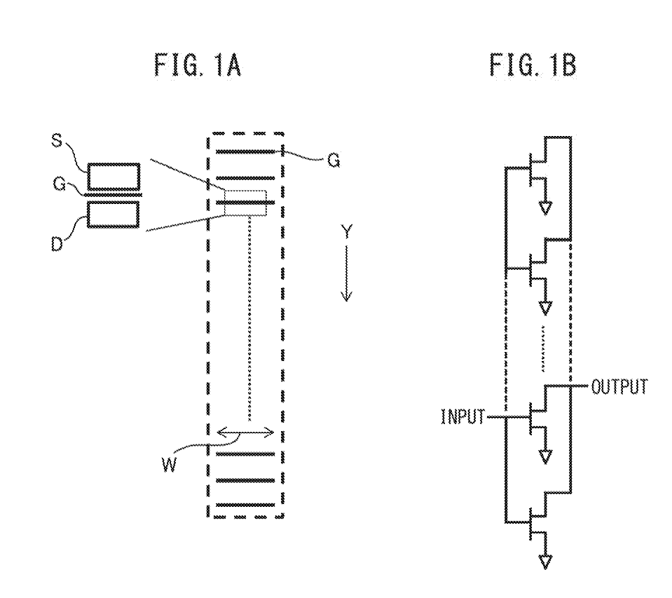

FIG. 1A and FIG. 1B are diagrams illustrating an arrangement example of a plurality of transistors and FIG. 1A illustrates a layout and FIG. 1B illustrates an equivalent circuit.

When a plurality of transistors are arranged, as illustrated in FIG. 1A, a plurality of gate electrodes are arranged pectinate in the direction (Y-direction) perpendicular to the lengthwise direction (X-direction) of a gate electrode G. A number of electrodes arranged pectinate are referred to as a gate finger. As illustrated in a partially enlarged view, the gate electrode G is arranged on the surface of the active region of the semiconductor substrate and on both sides of the active region (channel region) in which the gate electrode G is arranged, first and second electrically conductive regions corresponding to the source and the drain are arranged. A source electrode S and a drain electrode D are arranged on the first and second electrically conductive regions. A region including one set of the gate electrode G, the source electrode S, and the drain electrode D corresponds to one transistor, and a plurality of transistors are formed in FIG. 1A. As will be described later, the gate electrode is arranged on both sides of the source electrode S and the drain electrode D, respectively, and except for both ends, the one source electrode S and the one drain electrode D function as the source electrode S and the drain electrode D of two transistors.

The gate electrodes G and the drain electrodes D of the plurality of transistors are respectively connected in common to connection electrodes, not illustrated, and each of the connection electrodes is connected to a pad arranged on the periphery of the semiconductor substrate (chip). For example, the plurality of gate electrodes G are connected in common to a gate connection electrode arranged on the left side in FIG. 1A and the gate connection electrode forms an input terminal of the amplifier. The plurality of drain electrodes D are connected in common to a drain connection electrode arranged on the right side in FIG. 1A and the drain connection electrode forms an output terminal of the amplifier. The source electrodes S are connected in common to a source connection electrode arranged on the lower side and the source connection electrode forms a source terminal that is grounded. The source connection electrode may be arranged in parallel to the gate connection electrode or the drain connection electrode and connected so as to stride the other electrode.

Thus, the plurality of transistors connected so as to stride the other electrode have the equivalent circuit illustrated in FIG. 1B and the source terminal is grounded, a signal is input to the gate terminal, and a signal is output from the drain terminal.

In FIG. 1A, W indicates the gate width (unit gate width) of each transistor. As described previously, when the gate width of the transistor is increased, the gate resistance increases and the gain may be remarkably reduced in the high-frequency region, and therefore the maximum value of the unit gate width W may be limited.

As illustrated in FIG. 1A and FIG. 1B, although the total gate width increases by arranging a number of gate fingers, a transistor region for the arrangement becomes large and the length in the Y-direction of the chip is determined by the product of the pitch of the gate finger and the number of gate fingers. Thus, when the length in the Y-direction is limited, the number of gate fingers, i.e., the total gate width is also limited accordingly.

The density of transistors may be increased in order to increase the total gate width of the transistors while keeping the fixed length in the Y-direction of the chip region. However, if the density of transistors is increased, heat generated in the transistors stagnates and the temperature of the chip rises. The amplification gain may be reduced by increasing the temperature.

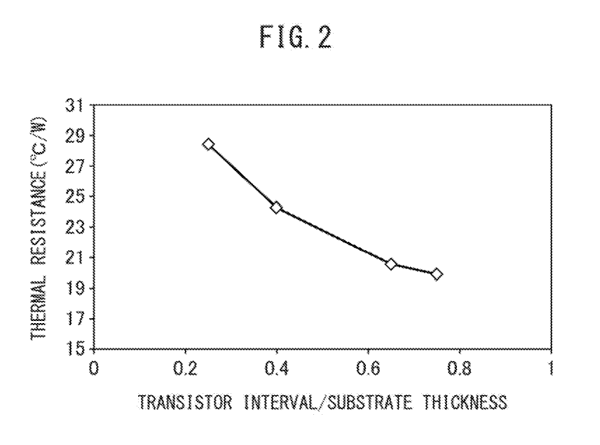

FIG. 2 illustrates a change in thermal resistance of a chip for the gate finger interval (pitch) of a transistor normalized by the substrate thickness. FIG. 2 illustrates that the thermal resistance increases and the temperature becomes higher as the transistor interval is reduced. The values of the thermal resistance used in FIG. 2 are those described in Non-Patent Document 1.

a plurality of gate finger rows may be arranged in the lengthwise direction (X-direction) of the gate electrode, in order to further increase the number of transistors arranged in the chip region. In other words, a plurality of transistors are arranged two-dimensionally. The chip size in the X-direction is determined by the product of the sum of the unit gate width and the width of the isolation region, and the number of gate finger rows.

In the above-described two-dimensional arrangement, a number of transistors may be arranged in the chip region and the gate electrode, the source electrode, and the drain electrode of the transistor are connected to the pads on the periphery of the chip region by each of the connection electrodes (connection wires). However, the drain electrode or the like is connected by the wire on the semiconductor substrate, and therefore a parasitic capacitance occurs accordingly. Thus, the gain in the signal path that connects the drain electrode of the transistor is reduced in high frequencies by the parasitic capacitance between the drain and the source. when the gain is reduced in high frequencies, the output power is reduced and the power efficiency is reduced.

In embodiments explained in the following, a semiconductor device is disclosed, which increases output power by having a number of transistors and which has a high-frequency power amplifier whose reduction in gain and efficiency in high frequencies is small.

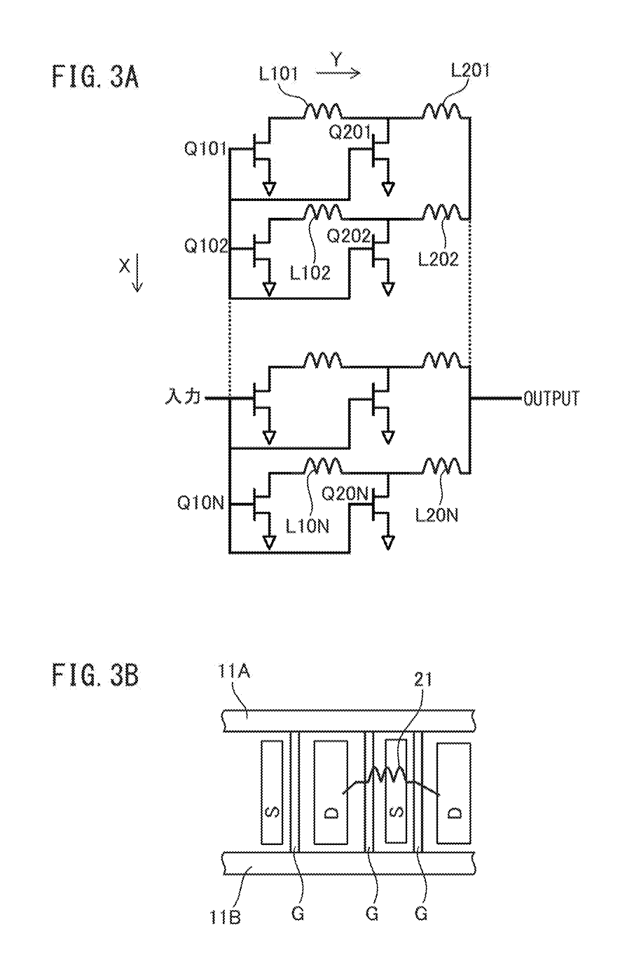

FIG. 3A and FIG. 3B are diagrams illustrating a configuration of a high-frequency power amplifier of a first embodiment and FIG. 3A illustrates a circuit diagram and FIG. 3B illustrates part of a layout.

As illustrated in FIG. 3A, a high-frequency power amplifier of the first embodiment has a plurality of transistors Q101 to Q10N and Q201 to Q20N arranged two-dimensionally. The vertical direction in FIG. 3A is the lengthwise direction (X-direction) of the gate electrode of each transistor and the horizontal direction is the Y-direction perpendicular to the X-direction. A plurality of gate fingers of a plurality of the transistors Q101 and Q201 arranged in the Y-direction form a gate finger row. In the X-direction, a plurality of gate finger rows are arranged in parallel. Although the example in which the gate finger row has two gate fingers is illustrated, explanation is given on the assumption that the gate finger row has three or more gate fingers actually.

The arrangement pitch between the transistors Q101 and Q201 adjacent to each other in the Y-direction, i.e., the gate finger interval between Q101 and Q201 is set to about 0.4 times to twice the thickness of the semiconductor substrate.

As illustrated in FIG. 3A, the source terminals (electrodes) of a plurality of transistors are connected in common to the source connection electrode arranged on the substrate side via vias and grounded. In the following, explanation is given on the assumption that the source connection electrodes are connected in common to the source connection electrode arranged on the substrate side via vias, and the diagrammatic representation of the source connection electrode is omitted. The source connection electrode may be arranged in another form. The gate terminals (electrodes) of the plurality of transistors arranged in the Y-direction are connected in common and further, the gate terminals (electrodes) of the plurality of transistors at the left end of each of the rows are connected in common. The drain terminals of the plurality of transistors arranged in the Y-direction are connected so that the drain terminals of the adjacent transistors are connected in sequence via inductance elements (inductors) L101 to 10N and L201 to L20N, and further, the drain terminals of the plurality of transistors at the right end of each of the rows are connected in common.

FIG. 3B illustrates part of a layout of one transistor row in the Y-direction in the first embodiment. The first and second electrically conductive regions are arranged alternately on both sides of the active region of the semiconductor substrate on which the gate electrode G is arranged and the source electrode S and the drain electrode D are arranged thereon. The transistor is formed in the region in which one gate electrode and the source electrode and the drain electrode on both sides thereof are formed. Thus, the source electrode S and the drain electrode D function as the source electrode and the drain electrode of the two adjacent transistors, and three transistors are illustrated in FIG. 3B.

In FIG. 3B, a first gate connection electrode 11A is arranged on the upper side of the row of the gate electrode, the source electrode, and the drain electrode, and a second gate connection electrode 11B is arranged on the lower side thereof, The plurality of the gate electrodes G are connected to the first gate connection electrode 11A and the second gate connection electrode 11B. The adjacent drain electrodes D are connected by a wire 21 including an inductor. As described previously, the source electrode is connected to the source connection electrode on the lower side, and therefore the source electrode is not illustrated. The layout in FIG. 3B has a length corresponding to the number of transistors in the Y-direction and the same layouts are arranged in the number corresponding to the number of the plurality of transistor rows arranged in the X-direction. As described previously, a plurality of sets of the first gate connection electrode 11A and the second gate connection electrode 11B are connected in common at the left end and is connected to the input signal pad on the periphery, not illustrated. The drain electrode at the left end of each row is connected in common via the wire 21 including an inductor and is connected to the output signal pad on the periphery, not illustrated.

Thus, the drain electrode of the two transistors is exactly common and the drain electrode of the two transistors is connected to the drain electrode of the adjacent two transistors via the wire 21 including an inductor. This means that each transistor in FIG. 3A is regarded as indicating two transistors together.

An inductance value L of the inductor of the drain connection electrode that connects the adjacent drain electrodes D is set so as to satisfy expressions (1) and (2) below and so that the ratio of the inductance value L and a parasitic capacitance C_{ds} between the drain and source electrodes of the transistor is constant. Then, a characteristic impedance Z₀ of an L-C line consisting of the inductor and the parasitic capacitor is constant and a high-frequency power amplifier may operate up to a shut-off frequency f_{c}. Practically, it is desirable to set the characteristic impedance to about 20Ω to 100Ω.

Z₀=(L/C_{ds})^{1/2}: constant

f_{c}=1/(2π(L/C_{ds})^{1/2})

The connection electrode (wire) including an inductor, which connects between the drain electrodes, is formed by a spiral inductor formed by wire bonding, a wire air bridge, or a multilayer wire.

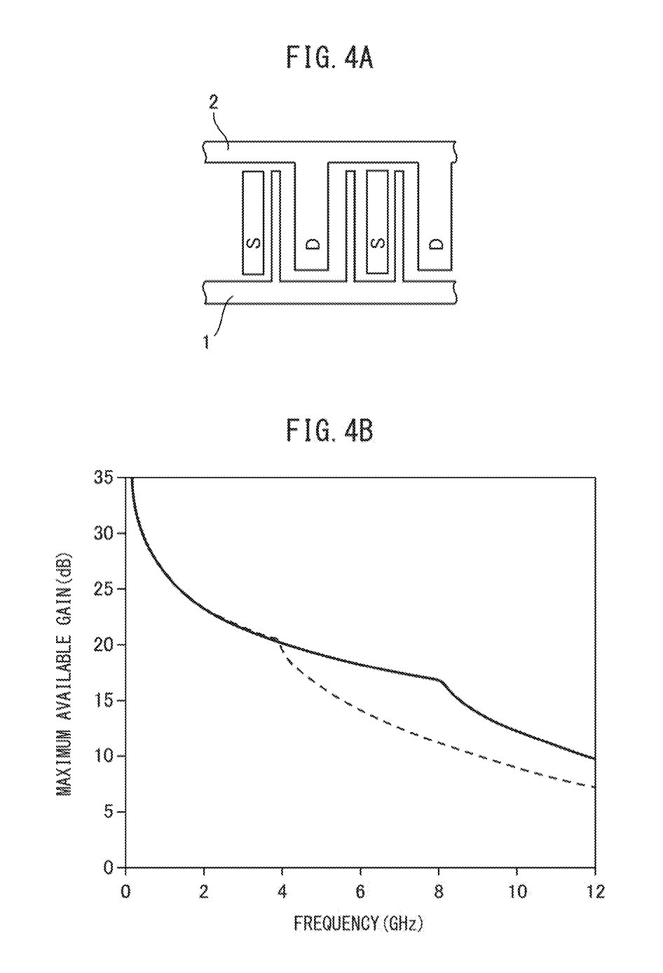

FIGS. 4A and 4B are diagrams illustrating measurement results of the frequency characteristics of the maximum available gain of the high-frequency power amplifier of the first embodiment, and FIG. 4A illustrates the layout of a comparative example described in FIG. 1, and FIG. 4B illustrates the frequency characteristics of the maximum available gain. In FIG. 4B, the horizontal axis represents the frequency and the vertical axis represents the maximum available gain (dB), and the solid line indicates the characteristics of the high-frequency power amplifier of the first embodiment and the dot line indicates the characteristics of the comparative example. The high-frequency power amplifiers of the first embodiment and the comparative example, whose characteristics were measured, have six gate fingers, i.e., twelve transistors and whose unit gate width is 320 μm.

The maximum available gain represents the gain that is obtained when the input portion and the output portion of the transistor perfectly aligns with each other. The high-frequency power amplifier of the first embodiment has a high gain up to high frequencies compared to that of the comparative example. In the first embodiment, both ends of the gate finger are connected to the first and second gate connection electrodes 11A and 11B and the equivalent gate resistance is ½ of that of the comparative example. Thus, the gain may be increased at high frequencies.

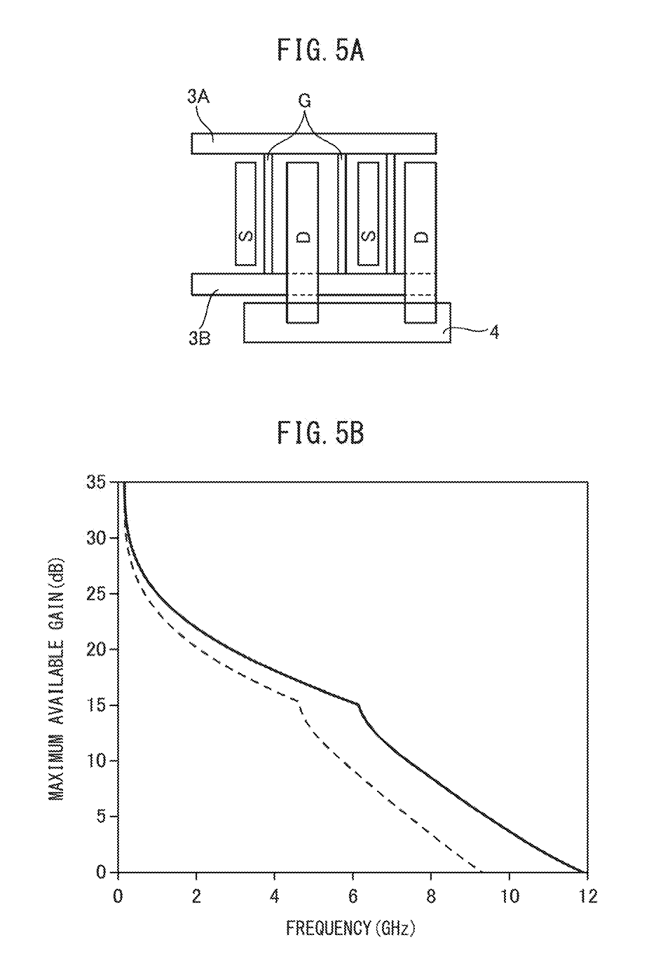

FIGS. 5A and 5B are diagrams illustrating the measurement results of the frequency characteristics of the maximum available gain of the high-frequency power amplifier of the first embodiment, and FIG. 5A illustrates the layout of the high-frequency power amplifier of the comparative example and FIG. 5B illustrates the frequency characteristics of the maximum available gain. The display in FIG. 5B is similar to the display in FIG. 4B.

As illustrated in FIG. 5A, in the comparative example, both ends of the gate electrode G (gate finger) are connected to first and second gate connection electrodes 3A and 3B and the equivalent gate resistance is ½ of that of the comparative example. This is the same as in the first embodiment. The drain electrode is connected to a drain connection electrode 4 arranged in parallel to the bottom side of the second gate connection electrode 3B in such a manner that the drain electrode strides the second connection electrode 3B. The second gate connection electrode 3B may stride the drain electrode 4. In other words, the first embodiment differs from the comparative example in FIG. 5A in that transistors in the first embodiment is connected to the adjacent transistors via inductance element (inductor), whereas transistors in the comparative example is connected to the adjacent transistors with no inductors having a predetermined inductance value.

The high-frequency power amplifies of the first embodiment and the comparative example, whose characteristics were measured, have 15 gate fingers, i.e., 29 GaN HEMT transistors, and the unit gate width is 320 μm. Further, in the first embodiment, the inductance value of the inductor is set to 30 pH so that the characteristic impedance of the L-C circuit with the capacitor between the drain and the source is 25Ω.

As illustrated in FIG. 5B, since a parasitic capacitance in the comparative example is lain between the drain and the gate, the gain is low compared to that of the characteristics of the first embodiment in the range from low frequencies to high frequencies.

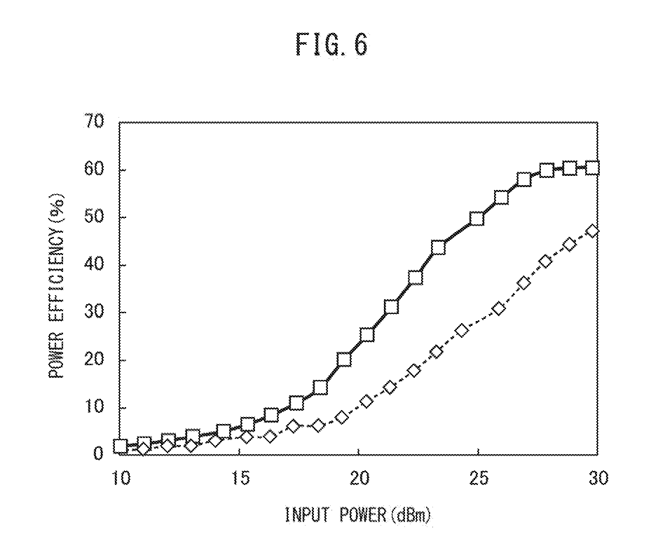

FIG. 6 is a diagram illustrating power efficiency of the high-frequency power amplifier of the first embodiment and that of the comparative example with the layout in FIG. 5A, and the solid line indicates the characteristics of the high-frequency power amplifier of the first embodiment and the dot line indicates the characteristics of the comparative example. As in the first embodiment, by providing the inductor (in the example also, 30 pH), the power efficiency increases by about 10 points.

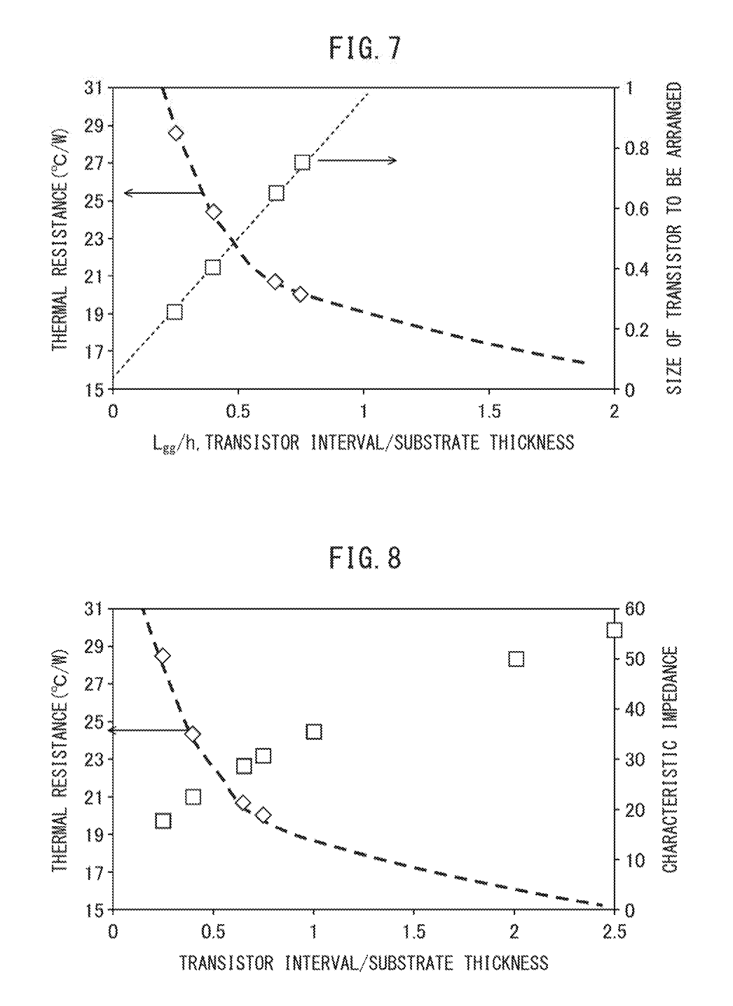

FIG. 7 is a diagram including a graph representing the change in thermal resistance of the chip for the transistor interval (pitch)/substrate thickness (L_{gg}/h) in FIG. 2, and a graph representing the size of a arranged transistor. The broken line indicates the change in thermal resistance and the dot line indicates the transistor size. In FIG. 7, the total gate width is 1 mm and the unit gate width is 100 μm (10 gate finger rows). When the transistor interval is small, the thermal resistance is high as described previously and the rise in temperature is large. When the interval is increased, the region for the transistor arranged increases. Thus, it is known that the transistor interval/substrate thickness is desirably 0.4 times to twice. The transistor interval is also advantageous in forming an inductor. The inductance of an inductor by wire bonding is about 0.75 nH to 1.2 nH per millimeter. If it is assumed that the substrate thickness is 100 μm, the transistor interval is 0.4 times when the inductance is about 30 pH to 48 pH, and favorable results are obtained.

FIG. 8 is a diagram in which a graph representing the characteristic impedance calculated from the inductance value L of the inductor and C_{ds} for the transistor interval is added in place of the graph representing the transistor size in FIG. 7. In FIG. 8, the second vertical axis (the vertical axis on the right side) represents the scale of the characteristic impedance. In FIG. 8, C_{ds} is assumed to be 60 fF. In the range in which the transistor interval to the substrate thickness is 0.4 times to twice, the characteristic impedance is about 20 to 50Ω, which is a practical range.

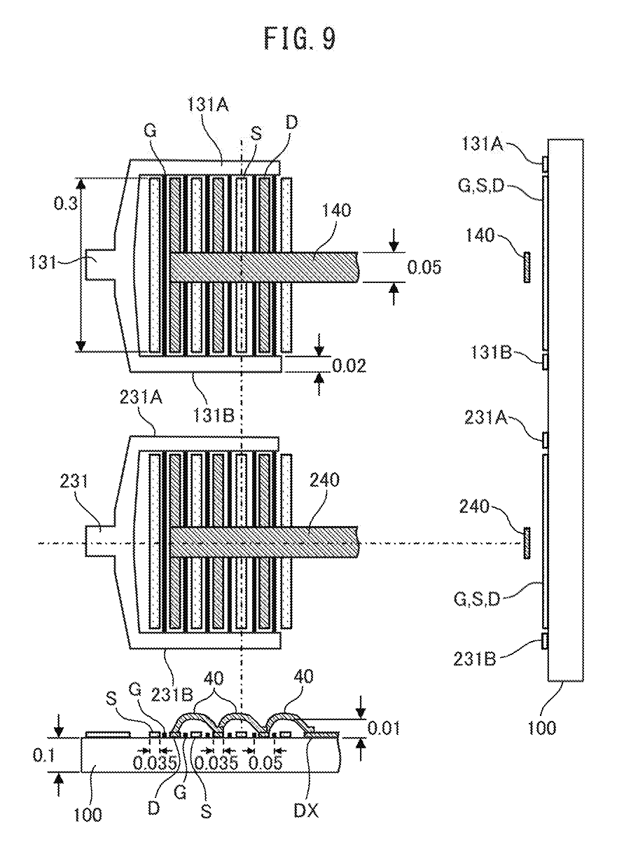

FIG. 9 is a diagram illustrating a layout configuration of a high-frequency power amplifier of a second embodiment, illustrating a top view and sectional views in two directions.

The high-frequency power amplifier of the second embodiment includes a plurality of GaN HEMT transistors in the two-dimensional arrangement in which the connection electrode (wire) including the inductor connecting between the drain electrodes D is implemented by an air bridge in the high-frequency power amplifier of the first embodiment. The plurality of GaN HEMT transistors are formed on a semiconductor substrate 100 having a thickness of 0.1 mm.

The transistor row corresponding to one gate finger row has the gate electrodes D having a length of 0.3 mm arranged at a 0.05 mm pitch and the source electrode S and the drain electrode D having a width of 0.35 mm arranged alternately on both sides of the gate electrode G, as illustrated. The gate electrode is formed on the active region on the surface of the semiconductor substrate 100. The source electrode S and the drain electrode D are arranged on first and second electrically conductive regions formed on the surface of the semiconductor substrate 100. The transistor row corresponding to one gate finger row has six gate electrodes (gate fingers), four source electrodes, and three drain electrodes. Thus, the transistor row corresponding to one gate finger row has six transistors. Since two gate finger rows are arranged, the transistor row has 12 transistors in total.

A first gate connection electrode 131A (231A) and a second gate connection electrode 131B (231B) are arranged on both sides of the gate electrode D, the source electrode S, and the drain electrode D (in FIG. 9, the top and bottom portions), and connected with the gate electrode G. The first gate connection electrode 131A and the second connection electrode 131B are connected to one gate connection electrode 131 on the left side. Similarly, the first gate connection electrode 231A and the second gate connection electrode 231B are connected to one gate connection electrode 231 on the left side. The gate connection electrodes 131 and 231 are further connected to the pads of the input signal terminals arranged on the periphery of the semiconductor substrate 100 (not illustrated).

The adjacent drain electrodes D are connected by an air bridge 40 having a height of 0.01 mm. The inductance value of the air bridge 40 having a center-to-center distance of 0.1 mm and a height of 0.01 mm is about 30 pH. The drain electrode D at the right end is connected to a drain extracting electrode DX by the air bridge 40. In FIG. 9, the air bridge 40 and the drain extracting electrode DX of the first row are indicated by a drain wire 140 and the air bridge 40 and the drain extracting electrode DX of the second row are indicated by a drain wire 240. The drain wire 140 and the drain wire 240 are further connected to the pads of the output signal terminals arranged on the periphery of the semiconductor substrate 100 (not illustrated). The height of the air bridge 40 is 0.01 mm.

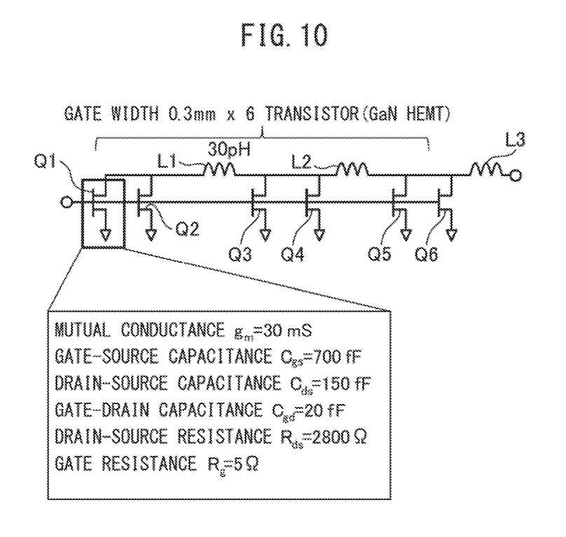

FIG. 10 is a diagram illustrating an equivalent circuit of the transistor row by one gate finger row of the high-frequency power amplifier of the second embodiment.

Adjacent two transistors of six transistors Q1 to Q6 corresponding to six gate fingers share the drain electrode. Thus, the drain (electrode) of the first and second transistors Q1 and Q2 is common and connected to the drain (electrode) common to the third and fourth transistors Q3 and Q4 via an inductor L1 (30 pH). Similarly, the drain (electrode) common to the third and fourth transistors Q3 and Q4 is connected to the drain (electrode) common to the fifth and sixth transistors Q5 and Q6 via an inductor L2 (30 pH). Further, the drain (electrode) common to the fifth and sixth transistors Q5 and Q6 is connected to the drain extracting electrode DX via an inductor L3 (30 pH). The drain extracting electrode DX is connected to the pad of the output signal terminal. The gates of the six transistors Q1 to Q6 are connected in common to the pad of the input signal terminal.

As illustrated in FIG. 10, in the configuration example, in the one transistor Q1, the mutual conductance gₘ=30 ms, the gate-source capacitance C_{gs}=700 fF, the drain-source capacitance C_{ds}=150 fF, the gate-drain capacitance C_{gd}=20 fF, the drain-source resistance R_{ds}=2,800Ω, and the gate resistance R_{g}=5Ω.

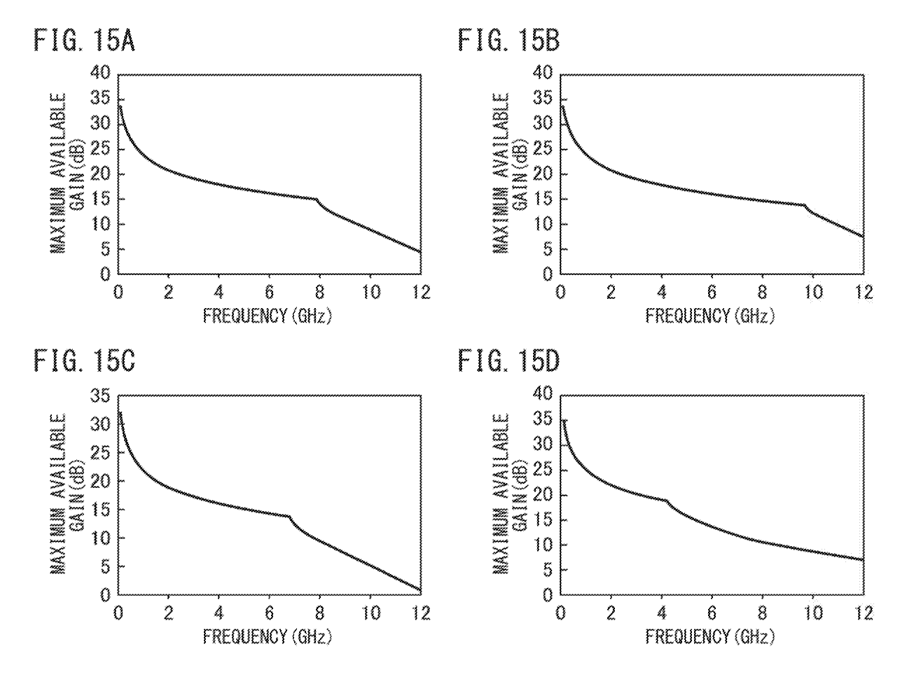

The graph illustrated in FIG. 15A indicates the frequency characteristics of the maximum available gain of the second embodiment by a simulation.

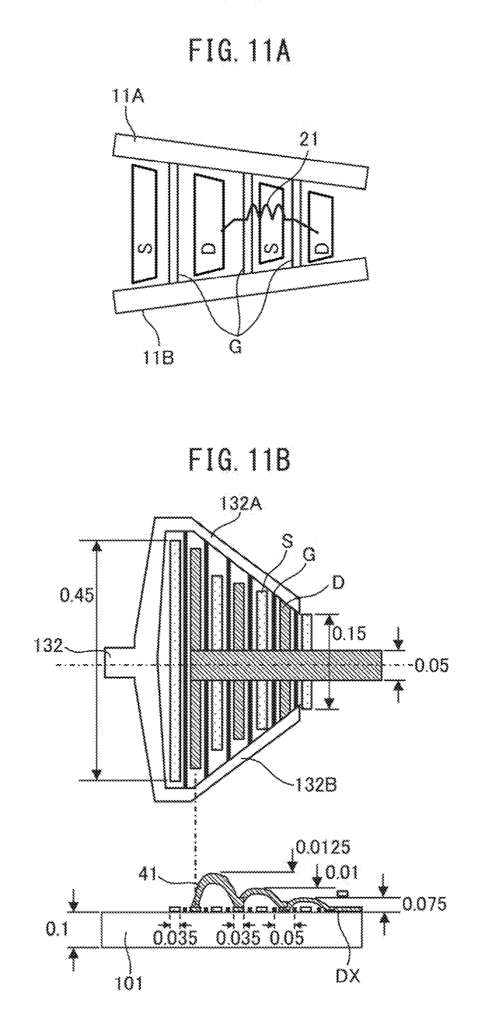

FIGS. 11A and 11B are diagrams illustrating a layout example of a transistor row corresponding to one gate finger row in a high-frequency power amplifier of a third embodiment, and FIG. 11A illustrates an outline layout and FIG. 11B illustrates a specific layout configuration.

As illustrated in FIG. 11A, although the high-frequency power amplifier of the third embodiment has a layout similar to that of the first embodiment illustrated in FIG. 3B, the high-frequency power amplifier of the third embodiment is different from that of the first embodiment in that the first and second gate connection electrodes 11A and 11B are inclined and the interval on the input side is wide compared to that on the output side. Thus, the widths of the source electrode S, the gate electrode G, and the drain electrode D that are arranged are wider on the input side and narrower on the output side.

As long as the relationship of expression (1) described previously is maintained, the transistor arrangement layout may be modified as in FIG. 11A. In the third embodiment, the drain-source capacitance Cₐₛ, which is a parasitic capacitance, becomes smaller from the input side toward the output side, and therefore the inductance value of the air bridge (inductor) that connects the drain electrode D is reduced in accordance with the change so as to satisfy expression (1).

Although the high-frequency power amplifier of the third embodiment has a layout similar to that of the second embodiment illustrated in FIG. 9, the high-frequency power amplifier of the third embodiment is different from that of the second embodiment in that the transistor row corresponding to the gate finger row has a layout illustrated in FIG. 11B, and the rest is the same.

As illustrated in FIG. 11B, in the transistor row corresponding to the gate finger row of the third embodiment, the arrangement of the source electrode S, the gate electrode G, the drain electrode D, and the drain extracting electrode DX in the advancement direction of the signal (from left to right in FIG. 11B) are the same as those of the second embodiment. However, the widths of the source electrode S, the gate electrode G, and the drain electrode D become smaller stepwise from the left end (input side) toward the right end (output side). Specifically, the width of the source electrode S at the left end (input side) is 0.45 mm, the width of the source electrode S at the right end (output side) is 0.15 mm, and the widths of the gate electrode G, the drain electrode D, and the source electrode S therebetween change in accordance with the change. Further, in accordance with the change, a first gate connection electrode 132A and a second gate connection electrode 132B are arranged inclined with respect to the advancement direction of the signal.

Further, an air bridge 41 that connects the first and second drain electrodes D has a height of 0.0125 mm and an inductance value of about 45 pH. The air bridge 41 that connects the second and third drain electrodes D has a height of 0.01 mm and an inductance value of about 30 pH. The air bridge 41 that connects the third drain electrode D and the drain extracting electrode DX has a height of 0.0075 mm and an inductance value of about 20 pH.

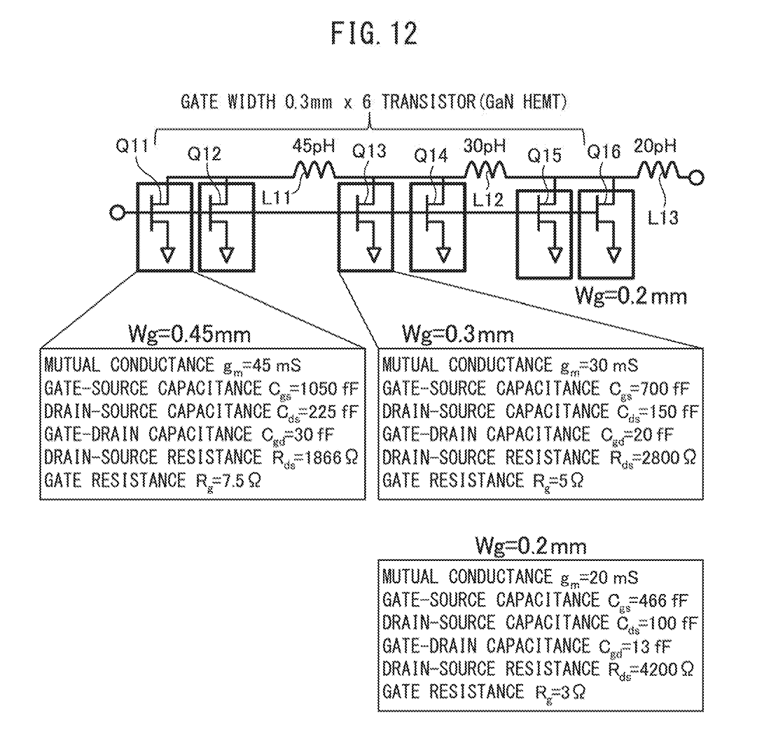

FIG. 12 is a diagram illustrating an equivalent circuit of the transistor row by one gate finger row of the high-frequency power amplifier of the third embodiment.

The drains of the first and second transistors Q11 and Q12 in six transistors Q11 to Q16 corresponding to six gate fingers are connected to the drains of the third and fourth transistors Q13 and Q14 via an inductor L11 (45 pH). Similarly, the drains of the third and fourth transistors Q13 and Q14 are connected to the drains of the fifth and sixth transistors Q15 and Q16 via an inductor L12 (30 pH). Further, the drains of the fifth and sixth transistors Q15 and Q16 are connected to the drain extracting electrode DX via an inductor L13 (20 pH).

In the transistor Q11, the gate width Wg=0.45 mm, the mutual conductance gₘ=45 ms, the gate-source capacitance C_{gs}=1,050 fF, the drain-source capacitance C_{ds}=225 fF, the gate-drain capacitance C_{gd}=30 fF, the drain-source resistance R_{ds}=1,866Ω, and the gate resistance R_{g}=7.5Ω. In the transistor Q13, the gate width Wg=0.3 mm, the mutual conductance gₘ=30 ms, the gate-source capacitance C_{gs}=700 fF, the drain-source capacitance C_{ds}=150 fF, the gate-drain capacitance C_{gd}=20 fF, the drain-source resistance R_{ds}=2,800Ω, and the gate resistance R_{g}=5Ω. In the transistor Q15, the gate width Wg=0.2 mm, the mutual conductance gₘ=20 ms, the gate-source capacitance C_{gs}=466 fF, the drain-source capacitance C_{ds}=100 fF, the gate-drain capacitance C_{gd}=13 fF, the drain-source resistance R_{ds}=4,200Ω, and the gate resistance R_{g}=3Ω. The characteristics of the other transistors Q12, Q14, and Q16 are obtained by assuming that the characteristics of the adjacent transistors change linearly.

The graph illustrated in FIG. 15B indicates the frequency characteristics of the maximum available gain of the third embodiment by a simulation.

The performance of the high-frequency power amplifiers of the second and third embodiment is compared with the performance of a conventional high-frequency power amplifier having a common configuration example.

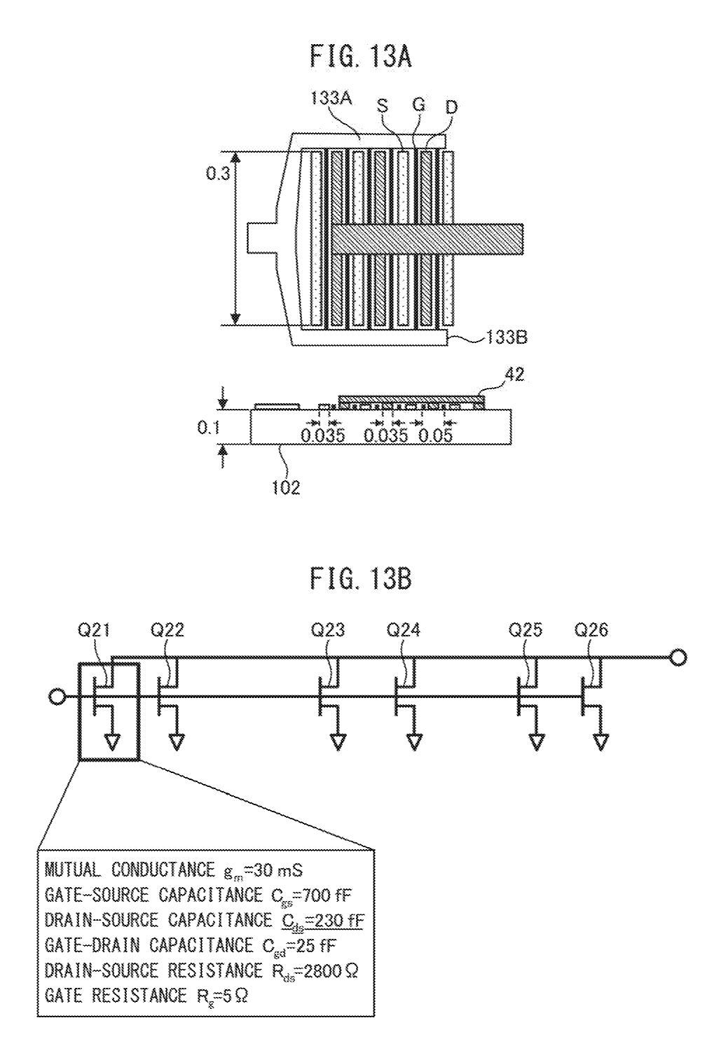

FIGS. 13A and 13B are diagrams illustrating a configuration of the transistor row corresponding to the one gate finger row in a high-frequency power amplifier of a first comparative example, and FIG. 13A illustrates a layout and FIG. 13B illustrates an equivalent circuit.

As illustrated in FIG. 13A, although the high-frequency power amplifier of the first comparative example has a layout similar to that of the second embodiment illustrated in FIG. 9, the high-frequency power amplifier of the first comparative example is different from that of the second embodiment in that the drain electrode D is connected by a planar wire 42 (142) in place of the air bridge. The other portions are the same as those of the second embodiment. Thus, the inductance value of the wire that connects between the drain electrodes D is small, and inductor is not arranged as illustrated in FIG. 13B. Thus, the relationship of expression (1) described previously is not satisfied.

In a transistor Q21, the mutual conductance gₘ=30 ms, the gate-source capacitance C_{gs}=700 fF, the drain-source capacitance C_{ds}=230 fF, the gate-drain capacitance C_{gd}=25 fF, the drain-source resistance R_{ds}=2,800Ω, and the gate resistance R_{g}=5Ω. Other transistors Q22 to Q26 also have the same characteristics. Thus, in the first comparative example, the drain-source capacitance C_{ds} is increased from 150 fF to 230 fF compared to the second embodiment.

The graph illustrated in FIG. 15C indicates the frequency characteristics of the maximum available gain of the first comparative example by a simulation.

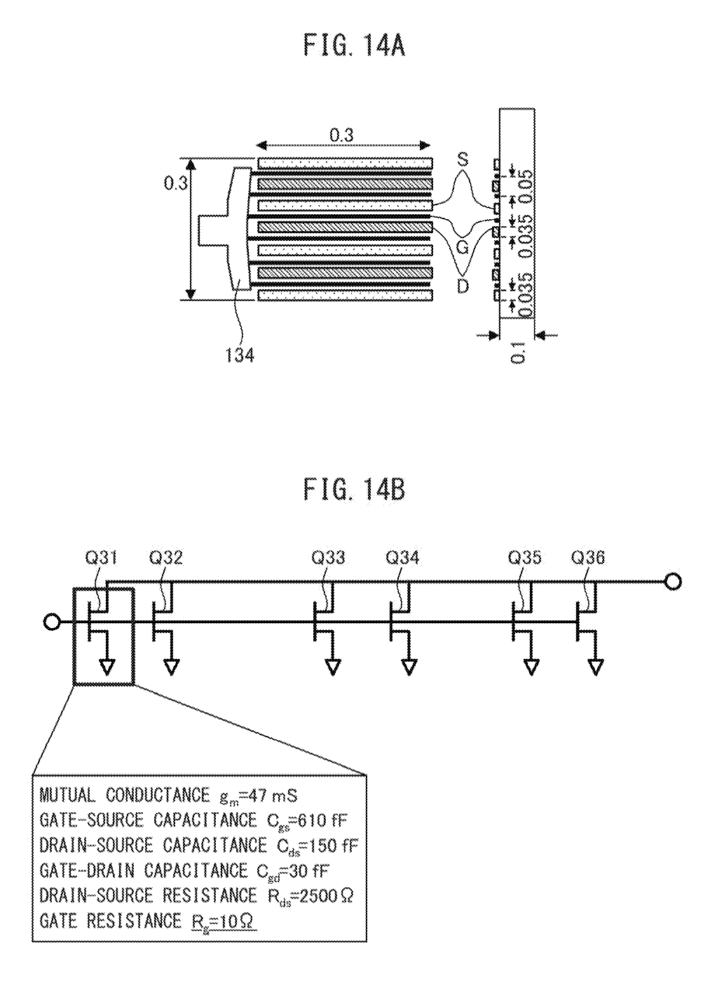

FIGS. 14A and 14B are diagrams illustrating a configuration of a transistor row corresponding to one gate finger row in a high-frequency power amplifier of a second comparative example, and FIG. 14A illustrates a layout and FIG. 14B illustrates an equivalent circuit.

As illustrated in FIG. 14A, the high-frequency power amplifier of the second comparative example has a common layout illustrated in FIG. 1 and FIG. 4A and a gate connection electrode 134 is arranged only at one end of each of the source electrode S, the gate electrode G, and the drain electrode D that are arranged. The drain connection electrode may be a planar wire that strides the source electrode S and the gate electrode G that are arranged and illustrated in FIG. 13A or an electrode arranged on the opposite side of the gate connection electrode 134 illustrated in FIG. 4A. In the second comparative example also, the inductance value of the wire that connects between the drain electrodes D is small, and therefore an inductor is not arranged as illustrated in FIG. 14B. Thus, the relationship of expression (1) described previously is not satisfied.

In a transistor Q31, the mutual conductance gₘ=47 ms, the gate-source capacitance C_{gs}=610 fF, the drain-source capacitance C_{ds}=150 fF, the gate-drain capacitance C_{gd}=30 fF, the drain-source resistance R_{ds}=2,500Ω, and the gate resistance R_{g}=10Ω. Other transistors Q32 to Q36 have the same characteristics. Thus, in the second comparative example, the gate resistance R_{g} is increased from 5Ω to 10Ω compared to the second embodiment.

The graph illustrated in FIG. 15D indicates the frequency characteristics of the maximum available gain of the second comparative example by a simulation.

As described above, FIGS. 15A to 15D illustrate the frequency characteristics of the maximum available gain in the high-frequency power amplifiers of the second embodiment, the third embodiment, the first comparative example, and the second comparative example. From these, the maximum available gain in the first comparative example is reduced rapidly at frequencies higher than the vicinity of 4 GHz. On the other hand, the maximum available gain in the second comparative example is maintained at comparatively high values up to the vicinity of 7 GHz and the high values are maintained up to frequencies higher than those of the first comparative example. The maximum available gain in the second embodiment is maintained at comparatively high values up to the vicinity of 8 GHz and the high values are maintained up to frequencies higher than those of the second comparative example. The maximum available gain in the third embodiment is maintained at comparatively high values up to the vicinity of 10 GHz and the high values are maintained up to frequencies further higher than those of the second comparative example.

All examples and conditional language provided herein are intended for pedagogical purposes of aiding the reader in understanding the invention and the concepts contributed by the inventor to furthering the art, and are to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising a semiconductor substrate and an amplifier formed on the semiconductor substrate, wherein
the amplifier comprises:
a plurality of finger electrodes arranged pectinate on the surface of an active region of the semiconductor substrate;
two gate connection electrodes that connect in common each of both ends of the plurality of gate finger electrodes;
a plurality of source electrodes and a plurality of drain electrodes arranged alternately on the surface of the semiconductor substrate between the plurality of gate finger electrodes; and
a plurality of drain connection elements that connect in sequence the plurality of drain electrodes, wherein
a ratio of an inductance value of each drain connection element to a parasitic capacitance of a drain-source electrode between the corresponding drain electrode and the source electrode is constant.

2. The semiconductor device according to claim 1, wherein
a pitch of the plurality of gate finger electrodes is 0.4 times to twice a thickness of the semiconductor substrate.

3. The semiconductor device according to claim 1, wherein
the plurality of drain connection elements are any of spiral wires formed by wire bonding, an air bridge, and a multilayer wire.

4. The semiconductor device according to claim 1, wherein
a gate width of the plurality of gate finger electrodes differs in order.

5. The semiconductor device according to claim 4, wherein
an inductance value of the plurality of drain connection elements differs in accordance with a change in the gate width of the plurality of gate finger electrodes.

6. The semiconductor device according to claim 1, comprising:
a plurality of transistor units including the gate electrode, the plurality of source electrodes, the plurality of drain electrodes, and the plurality of drain connection elements, wherein
the plurality of transistor units is arranged in a direction perpendicular to a direction in which the plurality of gate finger electrodes is arranged.

7. A transmitter having the semiconductor device according to claim 1.
